(19) United States
(12) Patent Application Publication
(10) Pub. No.: US 2014/0170315 A1
(43) Pub. Date: Jun. 19, 2014

(54) THIN FILM DEPOSITING APPARATUS AND THIN FILM DEPOSITION METHOD USING THE SAME

(71) Applicant: Seong-Jong KANG, Yongin-City (KR)

(72) Inventor: Seong-Jong KANG, Yongin-City (KR)

(21) Appl. No.: 13/905,172

(22) Filed: May 30, 2013

(30) Foreign Application Priority Data
Dec. 13, 2012 (KR) 10-2012-0145711

(51) Int. Cl. C23C 16/04

(52) U.S. Cl. CPC C23C 16/04
USPC 427/248.1; 118/720

(57) ABSTRACT

A thin-film deposition apparatus includes a deposition source, which ejects deposition vapors toward a substrate via an ejection hole, and an angle restricting plate, which is arranged adjacent to the ejection hole so as to restrict, within a set range, an angle of ejecting the deposition vapors from the ejection hole. The angle restricting plate includes a fixed restricting plate, which is fixed with respect to the ejection hole, and a movable restricting plate, which is movable with respect to the ejection hole.

### CROSS-REFERENCE TO RELATED APPLICATION

This application claims priority to Korean Patent Application No. 10-2012-0145711, filed on Dec. 13, 2012, in the Korean Intellectual Property Office, and entitled: “THIN FILM DEPOSITING APPARATUS AND THIN FILM DEPOSITING METHOD USING THE SAME,” which is incorporated by reference herein in its entirety.

### BACKGROUND

1. Field

Embodiments relate to a thin-film deposition apparatus and a thin-film deposition method using the same.

2. Description of the Related Art

A thin-film fabrication process may be used for formation of a thin-film, e.g., as an encapsulation of an organic light emitting display device. A deposition method may include generating vapor of a deposition source, such that a material of the deposition source is attached to a surface of a substrate.

### SUMMARY

Embodiments are directed to a thin-film deposition apparatus, including a deposition source, which ejects deposition vapors toward a substrate via an ejection hole; and an angle restricting plate, which is arranged adjacent to the ejection hole so as to restrict, within a set range, an angle of ejecting the deposition vapors from the ejection hole. The angle restricting plate may include a fixed restricting plate, which is fixed with respect to the ejection hole, and a movable restricting plate, which is movable with respect to the ejection hole.

The fixed restricting plate and the movable restricting plate may each be arranged adjacent to the ejection hole so as to restrict, within a set range, the angle of ejecting the deposition vapors from the ejection hole, and the movable restricting plate may be arranged to be able to slide with respect to the fixed restricting plate.

The movable restricting plate may be slidably arranged on an inner wall of the fixed restricting plate.

The movable restricting plate may include a plurality of movable restricting plates capable of independently sliding.

The plurality of movable restricting plates and the fixed restricting plate may be arranged such that sizes of openings formed by the plurality of movable restricting plates and the fixed restricting plate increase outward according to the set angle of ejecting.

The apparatus may further include an actuator that drives the movable restricting plate.

Embodiments are also directed to a method of depositing a thin-film, the method including providing an angle restricting plate, which is arranged nearby an ejection hole of a deposition source to restrict an angle of ejecting deposition vapors to an angle within a set range, the angle restricting plate including a fixed restricting plate, which is fixed with respect to the ejection hole, and a movable restricting plate, which is movable with respect to the ejection hole; performing a first deposition with an ejection angle restricted by using the movable restricting plate; relocating the movable restricting plate to move out of a position for restricting the ejection angle; and performing a second deposition with the ejection angle restricted by using the fixed restricting plate.

The movable restricting plate may be moved by sliding the movable restricting plate along an inner wall of the fixed restricting plate.

The movable restricting plate may include a plurality of movable restricting plates capable of independently sliding.

The plurality of movable restricting plates and the fixed restricting plate may be arranged such that sizes of openings formed by the plurality of movable restricting plates and the fixed restricting plate increase outward according to the set angle of ejecting, and restrictions of the ejection angle may be performed by using an innermost movable restricting plate to the fixed restricting plate in sequence starting with the innermost movable restricting plate, the fixed restricting plate being outermost.

The movable restricting plate may be moved by using an actuator.

### BRIEF DESCRIPTION OF THE DRAWINGS

Features will become apparent to those of skill in the art by describing in detail example embodiments with reference to the attached drawings in which:

FIG. 1 is a cross-sectional view of a thin-film deposition apparatus according to an example embodiment;

FIG. 2 is a diagram showing a driving mechanism of a movable restricting plate in the thin-film deposition apparatus shown in FIG. 1; and

FIGS. 3A through 3C are diagrams showing examples of using the thin-film deposition apparatus shown in FIG. 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “on” another element, it can be directly on the other element, or one or more intervening elements may also be present. It will also be understood that when an element is referred to as being “under” another element, it can be directly under, or one or more intervening elements may also be present. It will also be understood that when an element is referred to as being “between” two elements, it can be the only element between the two elements, or one or more intervening elements may also be present. Like reference numerals refer to like elements throughout.

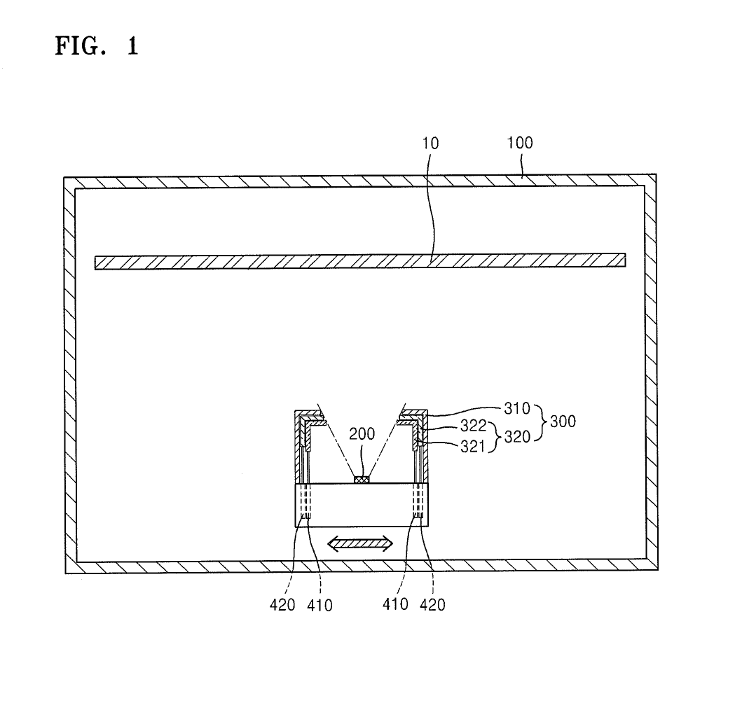

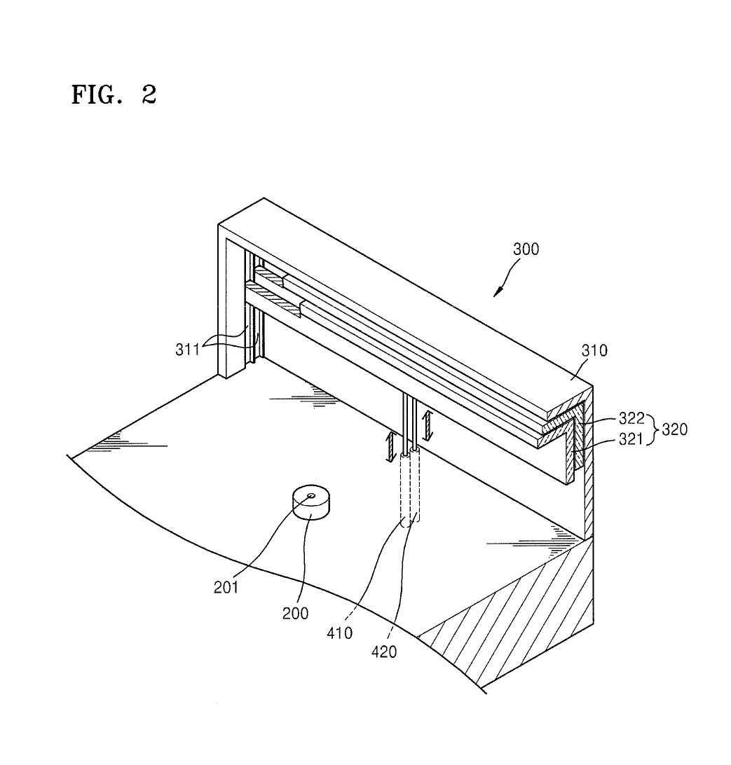

FIG. 1 is a cross-sectional view of a thin-film deposition apparatus according to an example embodiment, and FIG. 2 is a diagram showing a driving mechanism of a movable restricting plate 320 described below.

In the example embodiment shown in FIGS. 1 and 2, a thin-film deposition apparatus includes a chamber 100 in which a substrate 10 (deposition target) is fixed and a deposition source 200 which scan-moves inside the chamber 100 below the substrate 10 and ejects deposition vapors. When deposition begins, the deposition source 200 ejects deposition vapors, and the ejected deposition vapors are deposited to the substrate 10 and form a thin-film.

In the present example embodiment, an angle restricting plate 300 is arranged as a component for restricting an angle at which deposition vapors are ejected from the deposition source 200. Thus, deposition vapors may fly toward the substrate 10 only via an opening restricted by the angle restricting plate 300, thereby restricting a deposition region.

In the present example embodiment, the angle restricting plate 300 includes a fixed restricting plate 310 and the movable restricting plate 320. The fixed restricting plate 310 is fixedly arranged with respect to an ejection hole 201 of the deposition source 200 and guides deposition vapors of the deposition source 200 to travel toward the substrate 10 via an opening restricted by the fixed restricting plate 310. The movable restricting plate 320 is movably arranged with respect to the ejection hole 201 of the deposition source 200. In the present example embodiment, the movable restricting plate 320 and includes first and second movable restricting plates that may be arranged in multiple states, e.g., a first movable restricting plate 321 and a second movable restricting plate 322 are arranged to respectively slide with respect to the fixed restricting plate 310.

Referring to FIG. 2, the movable restricting plate 320 will be described below in detail.

In the present example embodiment, the movable restricting plate 320 includes the first movable restricting plate 321 and the second movable restricting plate 322, each of which is arranged to be able to slide along a guiding slot 311 formed in the fixed restricting plate 310.

Actuators 410 and 420 are respectively connected to the first and second movable restricting plate 321 and 322, and thus the first and second movable restricting plate 321 and 322 may be driven to independently slide relative to each other.

As shown in FIGS. 1 and 2, the first and second movable restricting plate 321 and 322 and the fixed restricting plate 310 form a structure in which openings formed by the first and second movable restricting plate 321 and 322 and the fixed restricting plate 310 become smaller inward. In other words, the opening formed by the innermost first movable restricting plate 321 is the smallest opening, and openings formed by the second movable restricting plate 322 and the fixed restricting plate 310 becomes larger outward in the order stated. The structure is to increase sizes of openings outward according to a deposition angle to maintain a restricted angle constant. The first and second movable restricting plates and the fixed restricting plate have edges that are protruded to the openings, and the opening formed by the edges of the innermost first movable restricting plate is the smallest opening, and openings formed by the edges of the second movable restricting plate 322 and the edges of the fixed restricting plate 310 becomes larger outward in the order stated.

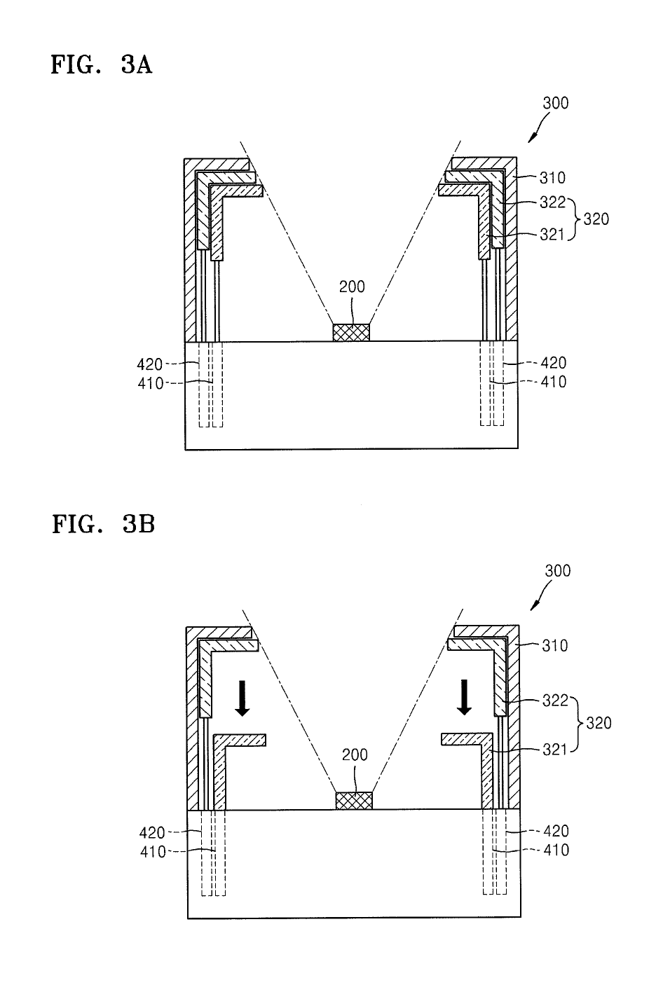

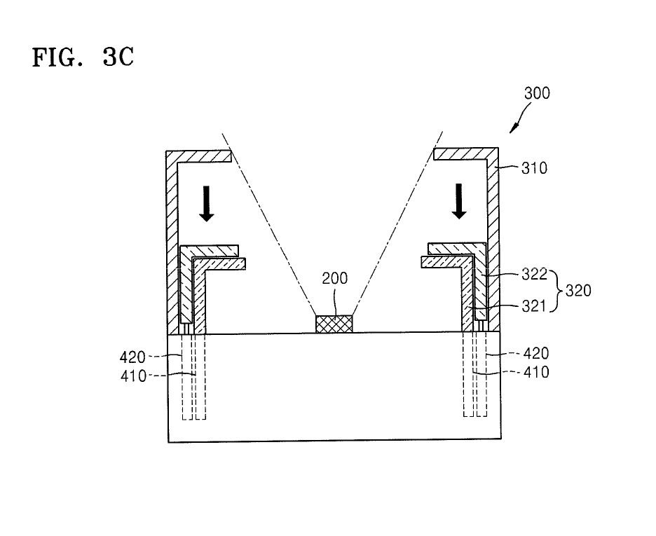

The thin-film deposition apparatus having the structure as described above may be operated as shown in FIGS. 3A through 3C.

First, the substrate 10 is mounted inside the chamber 100 to perform a deposition process.

Next, when the substrate 10 is mounted, the main deposition process is started by driving the deposition source 200.

As shown in FIG. 3A, deposition is initially started when the first and second movable restricting plate 321 and 322 and the fixed restricting plate 310 are most closely arranged to each other (e.g., they closely contact one another), that is, when the both first and second movable restricting plate 321 and 322 are elevated. At this point, the innermost first movable restricting plate 321 restricts a deposition angle. As shown in FIG. 3A, since the opening formed by the protruding edges of the first movable restricting plate 321 is the smallest opening, deposition vapors ejected form the ejection hole 201 of the deposition source 200 are restricted by the first movable restricting plate 321. As a result, the deposition vapors are ejected toward the substrate 10 within an angle restricted by the first movable restricting plate 321.

As depositions are repeatedly performed, deposition vapors are also attached to end portions of the first movable restricting plate 321, and thus the diameter of the opening gradually changes. Therefore, after performing depositions for a sufficient number of times, the angle restriction task is handed over to the other movable restricting plate 320. To this end, as shown in FIG. 3B, the actuator 410 connected to the first movable restricting plate 321 is driven, thereby automatically lowering the first movable restricting plate 321 down. As a result, the first movable restricting plate 321 moves out of a position at which the first movable restricting plate 321 was restricting a deposition angle, and the second movable restricting plate 322 takes over. Therefore, deposition may be resumed while a deposition restricting angle is almost constantly maintained.

When deposition vapors are attached to end portions of the second movable restricting plate 322 as time passes, the fixed restricting plate 310 takes over to restrict deposition angle. To this end, as shown in FIG. 3C, the actuator 420 connected to the second movable restricting plate 322 is driven, thereby automatically lowering the second movable restricting plate 322 down. As a result, the second movable restricting plate 322 moves out of a position at which the second movable restricting plate 322 was restricting a deposition angle, and the fixed restricting plate 310 takes over. Therefore, deposition may be resumed while a deposition restricting angle is almost constantly maintained.

When deposition angle restrictions are performed in turn as described above, depositions may be performed while a deposition angle is almost constantly maintained, and thus depositions may be performed very stably and uniformly.

Although the present example embodiment shows a structure in which the two movable restricting plates (the first and second movable restricting plates 321 and 322) constitute the movable restricting plate 320, more than two movable restricting plates may be arranged.

By way of summation and review, a method of restricting a deposition angle by attaching an angle restricting plate nearby a deposition source may be used to appropriately restrict an area deposited on a substrate. Thus, by installing the angle restricting plate around a vapor hole of the deposition source, vapors from the deposition source may be restricted such that deposition may be performed only at desired regions. As depositions are repeatedly performed, vapors of the deposition source may attach to the angle restricting plate. In such a case, a deposition angle may gradually deviate from an initially set deposition angle. This may result in an undesirable variation in deposition from one region to another.

As described above, embodiments relate to a thin-film deposition apparatus that generates vapor of a deposition source to deposit material from the deposition source onto a substrate, and more particularly, to a thin-film deposition apparatus that forms a thin-film with a restricted a deposition angle and a method of using the same. Embodiments may provide an enhanced thin-film deposition apparatus configured to provide a substantially constant deposition angle such that a deposition region defined by an angle restricting plate is substantially constant. A thin-film deposition apparatus according to an embodiment may help quickly and efficiently control a deposition region defined by an angle restricting plate, such that the deposition region is maintained substantially constant as time passes, so as to provide a method of stable and uniform thin-film deposition.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A thin-film deposition apparatus, comprising:
a deposition source, which ejects deposition vapors toward a substrate via an ejection hole; and
an angle restricting plate, which is arranged adjacent to the ejection hole so as to restrict, within a set range, an angle of ejecting the deposition vapors from the ejection hole,
wherein the angle restricting plate includes a fixed restricting plate, which is fixed with respect to the ejection hole, and a movable restricting plate, which is movable with respect to the ejection hole.

2. The apparatus as claimed in claim 1, wherein:
the fixed restricting plate and the movable restricting plate are each arranged adjacent to the ejection hole so as to restrict, within a set range, the angle of ejecting the deposition vapors from the ejection hole, and
the movable restricting plate is arranged to be able to slide with respect to the fixed restricting plate.

3. The apparatus as claimed in claim 2, wherein the movable restricting plate is slidably arranged on an inner wall of the fixed restricting plate.

4. The apparatus as claimed in claim 3, wherein the movable restricting plate includes a plurality of movable restricting plates capable of independently sliding.

5. The apparatus as claimed in claim 4, wherein the plurality of movable restricting plates and the fixed restricting plate are arranged such that sizes of openings formed by the plurality of movable restricting plates and the fixed restricting plate increase outward according to the set angle of ejecting.

6. The apparatus as claimed in claim 1, further comprising an actuator that drives the movable restricting plate.

7. A method of depositing a thin-film, the method comprising:
providing an angle restricting plate, which is arranged nearby an ejection hole of a deposition source to restrict an angle of ejecting deposition vapors to an angle within a set range, the angle restricting plate including a fixed restricting plate, which is fixed with respect to the ejection hole, and a movable restricting plate, which is movable with respect to the ejection hole;
performing a first deposition with an ejection angle restricted by using the movable restricting plate;
relocating the movable restricting plate to move out of a position for restricting the ejection angle; and
performing a second deposition with the ejection angle restricted by using the fixed restricting plate.

8. The method as claimed in claim 7, wherein the movable restricting plate is moved by sliding the movable restricting plate along an inner wall of the fixed restricting plate.

9. The method as claimed in claim 8, wherein the movable restricting plate includes a plurality of movable restricting plates capable of independently sliding.

10. The method as claimed in claim 9, wherein:
the plurality of movable restricting plates and the fixed restricting plate are arranged such that sizes of openings formed by the plurality of movable restricting plates and the fixed restricting plate increase outward according to the set angle of ejecting, and
restrictions of the ejection angle are performed by using an innermost movable restricting plate to the fixed restricting plate in sequence starting with the innermost movable restricting plate, the fixed restricting plate being outermost.

11. The apparatus as claimed in claim 7, wherein the movable restricting plate is moved by using an actuator.
